(19) United States
(12) Patent Application Publication
(10) Pub. No.: US 2025/0278139 A1
(43) Pub. Date: Sep. 4, 2025

(54) TWO-FUNCTION PUSH TRIGGER

(71) Applicant: Qorvo US, Inc., Greensboro, NC (US)

(72) Inventor: Omar Leung, Palo Alto, CA (US)

(21) Appl. No.: 19/049,094

(22) Filed: Feb. 10, 2025

Related U.S. Application Data
(60) Provisional application No. 63/560,839, filed on Mar. 4, 2024.

(51) Int. Cl. G06F 3/01; G06F 3/041; H03K 17/96

(52) U.S. Cl. CPC G06F 3/016; H03K 17/962; G06F 3/0414; H03K 2217/96062

(57) ABSTRACT

A two-function push trigger is disclosed. In one aspect, the trigger includes a first switch, which may be mechanical in nature and may be considered a first force sensor, that activates a primary function when a first force is applied, along with a second force sensor that activates a secondary function when a second force less than the first force is applied. A tactile or haptic feedback may be provided when the second force is detected to alert the user that the desired force for secondary function activation has been used. By providing this second sensor and feedback, users may avoid inadvertent application of too much force and avoid unintended primary function activation.

### PRIORITY APPLICATION

The present application is related to U.S. Provisional Patent Application Ser. No. 63/560,839 filed on Mar. 4, 2024, and entitled “TWO-FUNCTION PUSH TRIGGER,” the contents of which are incorporated herein by reference in its entirety.

### BACKGROUND

### I. Field of the Disclosure

The technology of the disclosure relates generally to manual push triggers that have two activation points that initiate different actions.

### II. Background

Handheld devices abound in modern society. Many such devices include one or more buttons that actuate functions on such devices. In many cases, there may be pressure to combine functions into a single button. Examples include but are not limited to the autofocus function and picture-taking function of digital cameras or the fingerprint authentication function and clear or close screen on some mobile communication devices. Still, other combinations or devices may exist. In many cases, a user attempting to actuate the first function may inadvertently trigger the second function. Thus, there is room for innovation to improve the user experience with such two function triggers.

### SUMMARY

Aspects disclosed in the detailed description include a two-function push trigger. In particular, aspects of the present disclosure contemplate a first switch, which may be mechanical in nature and may be considered a first force sensor, that activates a primary function when a first force is applied, along with a second force sensor that activates a secondary function when a second force less than the first force is applied. A tactile or haptic feedback may be provided when the second force is detected to alert the user that the desired force for secondary function activation has been used. By providing this second sensor and feedback, users may avoid the inadvertent application of too much force and avoid unintended primary function activation.

In this regard, in one aspect, a two-function trigger system is included. The two-function trigger system includes a contact configured to respond to a user's touch and a first force sensor mechanically coupled to the contact and configured to actuate a first function when a first force threshold is reached or exceeded. The two-function trigger system also includes a control circuit, a second force sensor coupled to the contact and configured to actuate a second function through the control circuit when a second force threshold is reached, the second force threshold less than the first force threshold, and a feedback circuit coupled to the control circuit, the feedback circuit configured to provide feedback to a user responsive to the second force threshold being reached.

In another aspect, a device is disclosed. The device includes a user interface comprising a contact and a two-function trigger system associated with the contact, the two-function trigger system comprising a first force sensor mechanically coupled to the contact and configured to actuate a first function when a first force threshold is reached or exceeded. The device also includes a control circuit, a second force sensor coupled to the contact and configured to actuate a second function through the control circuit when a second force threshold is reached, the second force threshold less than the first force threshold, and a feedback circuit coupled to the control circuit, the feedback circuit configured to provide feedback to the user responsive to the second force threshold being reached.

In another aspect, a method of actuating a two-function trigger is disclosed. The method includes pressing a contact with force less than a first force threshold but equal to or greater than a second force threshold, responsive to the second force threshold being met, actuating a second function in a device and providing feedback to a user, and responsive to the first force threshold being met, actuating a first function in the device.

### BRIEF DESCRIPTION OF THE DRAWINGS

FIG. 1 is a cross-sectional elevational view of a conventional two-function trigger in a device;

FIG. 2 is a cross-sectional elevational view of an exemplary two-function trigger with two force sensors according to aspects of the present disclosure;

FIG. 3 is a cross-sectional elevational view of an exemplary two-function trigger with a second force sensor positioned beneath the first force sensor, according to aspects of the present disclosure;

FIG. 4 is a cross-sectional elevational view of an exemplary two-function trigger with a second force sensor positioned beside the first force sensor according to aspects of the present disclosure;

FIG. 5 is a block diagram of an exemplary system that may be implemented as any of the examples of FIGS. 2-4;

FIG. 6 is a flowchart illustrating an exemplary process for using the two-function trigger of the present disclosure; and

FIG. 7 is a block diagram of a mobile terminal, which may include the two-function trigger of FIGS. 2-5 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a two-function push trigger. In particular, aspects of the present disclosure contemplate a first switch, which may be mechanical in nature and may be considered a first force sensor, that activates a primary function when a first force is applied, along with a second force sensor that activates a secondary function when a second force less than the first force is applied. A tactile or haptic feedback may be provided when the second force is detected to alert the user that the desired force for secondary function activation has been used. By providing this second sensor and feedback, users may avoid the inadvertent application of too much force and avoid unintended primary function activation.

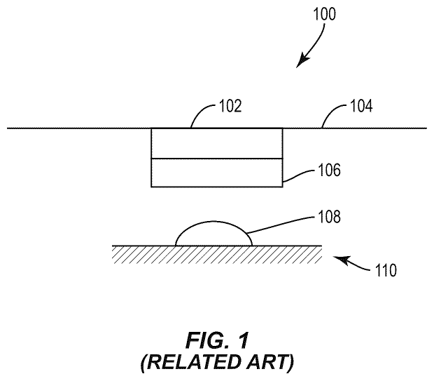

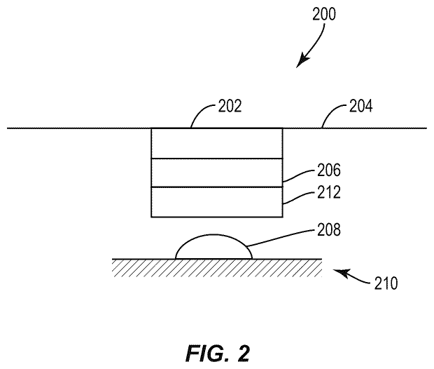

Before addressing aspects of the present disclosure, a brief overview of a conventional two-function trigger is provided with reference to FIG. 1. Against this background, aspects of the present disclosure are discussed beginning with reference to FIG. 2.

In this regard, FIG. 1 is a cross-sectional elevational view of a two-function trigger 100. For the purposes of illustration, it is assumed that the two-function trigger 100 is a touch button on a mobile terminal (not specifically shown), such as a cell phone that includes a fingerprint reader function. Thus, the two-function trigger 100 includes a button 102 that is generally flush with an external surface 104 of the mobile terminal. The button 102 is positioned over or associated with a fingerprint sensor 106. Depression of the button 102 deforms a mechanical dome switch 108 positioned on a chassis 110 (or other essentially rigid and immovable surface) of the mobile terminal.

Such conventional two-function triggers 100 will actuate and capture a fingerprint of a finger as the finger approaches or contacts the button 102 and also a second function, commonly to close an active application or turn off the screen of the mobile terminal. For many uses, this two-function approach is sensible in that it preserves valuable real estate on the mobile terminal and allows a user to unlock the mobile terminal using the biometric validation of the fingerprint sensor and also close applications or the screen in normal use. However, many applications require secondary authentication. For example, a banking application may ask for a fingerprint to access account information after opening the application (e.g., by tapping the bank application icon). While careful users may experience little difficulty in actuating the fingerprint sensor without depressing the button 102, others may press the button 102 with sufficient force to close the application or turn off the screen, necessitating starting over. This repetition may lead to a poor consumer experience. Two solutions are conventionally provided. The first is not really a solution but relies on training the user to press lightly enough that the dome switch 108 is not actuated. The second is to require a press and hold to action to close the application or lock the screen. While this approach sufficiently separates the two functions, it will add latency to the user experience.

A second issue may arise in the actual fingerprint sensor 106. A fingerprint may have a different appearance to the sensor 106 depending on the pressure applied (a light touch may have readily discernable ridges and valleys while a heavy touch may be squashed). Thus, if the user varies the force applied relative to the initial recognition training, the user may experience false rejection from using inconsistent pressure.

Thus, the variability in user experience from the combined two-function trigger leads to opportunities for improvement. Aspects of the present disclosure contemplate adding a second force sensor to the two-function trigger that causes one function to trigger at a predefined force while providing feedback that allows the user to know the appropriate predefined force has been applied. Force in excess of this predefined force will actuate the first force sensor (e.g., the dome switch) to actuate the other function (e.g., close the application or lock the screen).

FIGS. 2-4 illustrate various placement options for the force sensor. In an exemplary aspect, the force sensor may be Qorvo part QM98000 or a capacitive element that has two plates whose relative position changes as a function of force, thereby changing the capacitance according to the well-known formula C=ε*a1*a2/d, where C is the capacitance, ε is the dielectric constant of the intervening material a1, a2 are the respective area of the plates and d is the distance between the plates. A known current or voltage may be applied to the two plates and measured to derive C(d). When C(d) is at a predefined threshold, the associated function may be actuated. Other force sensors may also be used without departing from the present disclosure.

In this regard, FIG. 2 illustrates a two-function trigger 200. The two-function trigger 200 includes a button 202 that is generally flush with an external surface 204 of the mobile terminal. The button 202 is positioned over or associated with a fingerprint sensor 206. Depression of the button 202 deforms a first force sensor (e.g., a mechanical dome switch) 208 positioned on a chassis 210 (or other essentially rigid and immovable surface) of a mobile terminal. A second force sensor 212 is positioned between the fingerprint sensor 206 and the first force sensor 208. The first force sensor 208 is configured to actuate a first function on the application of a force exceeding a first threshold (e.g., on complete compression of the dome switch). The second force sensor 212 is configured to actuate a second function after the application of a force above a second threshold but below the first threshold. In an exemplary aspect, the first function closes an application or locks a screen on a mobile terminal, and the second function actuates the fingerprint sensor 206.

As explained below, actuating the second function may be accompanied by some form of feedback discernable to the user (e.g., tactile or haptic (e.g., vibration) or audible (e.g., a tone)).

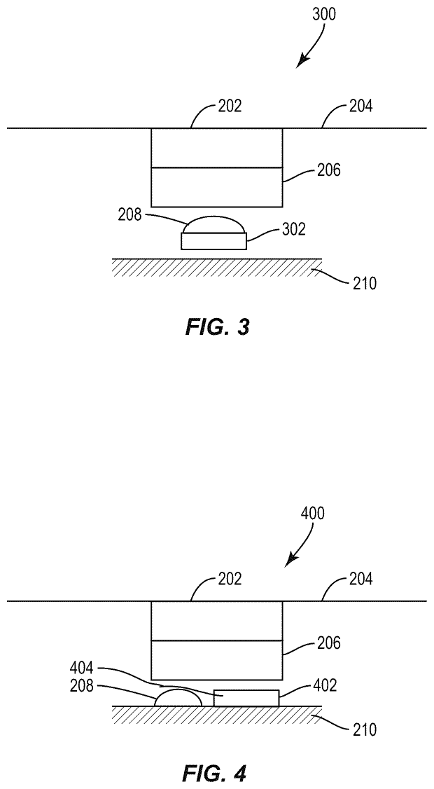

Similarly, FIGS. 3 and 4 illustrate two-function triggers 300 and 400, respectively, which share many of the same parts, but in FIG. 3, the second force sensor 302 is positioned beneath the first force sensor 208, either in the chassis 210 or on a top surface of the chassis 210. In FIG. 4, the second force sensor 402 is positioned beside the first force sensor 208 and may be actuated by some form of lever 404.

By adding the second force sensor 212, 302, 402, it is now possible to actuate the second function at a known force, for example, between 0.5 and 3 Newtons. Further, because the second force sensor reads at a consistent force, force variable functions, like fingerprint reading, are actuated at the same force (not too light and not overly mashed). This consistency allows for the initial setup of quality finger images, which are then consistently compared to the same level of force for proper evaluation of the biometric data. Note that when the second function is fingerprint detection, it may be possible to incorporate the second force sensor into the fingerprint sensor 206.

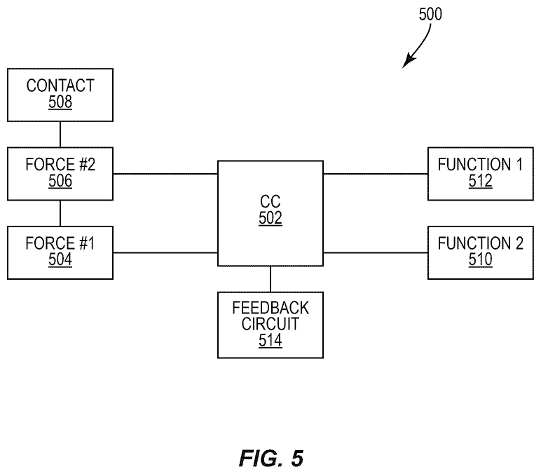

A block diagram of a two-function trigger system 500 is provided in FIG. 5, with the understanding that any of the examples above may be incorporated into the system 500. More particularly, the system 500 may include a control circuit 502, which may, for example, be an application processor or the like. The control circuit 502 communicates with a first force sensor 504 (e.g., a dome switch or the like) and a second force sensor 506 (e.g., force sensor 212, 302, 402). A contact or button 508 may move in such a fashion as to exert a force on the first force sensor 504 and the second force sensor 506 concurrently. When the force exerted and detected exceeds a second threshold, the control circuit 502 may activate a second function that is controlled by a second function circuit 510 (e.g., a fingerprint sensor). When the force exerted and detected exceeds a first threshold greater than the second threshold, the control circuit 502 may activate a first function that is controlled by a first function circuit 512. The system 500 further includes a feedback circuit 514, which may provide haptic, tactile, visual, or audible feedback to the user when the first or second force threshold is reached.

The use of first and second in this context is for clarity, and it should be appreciated that, as used, the order is inverted relative to a normal discussion. However, because the first function is generally associated with the intuitive or default purpose of the button or contact 508, such a default function is given primacy over the auxiliary second function.

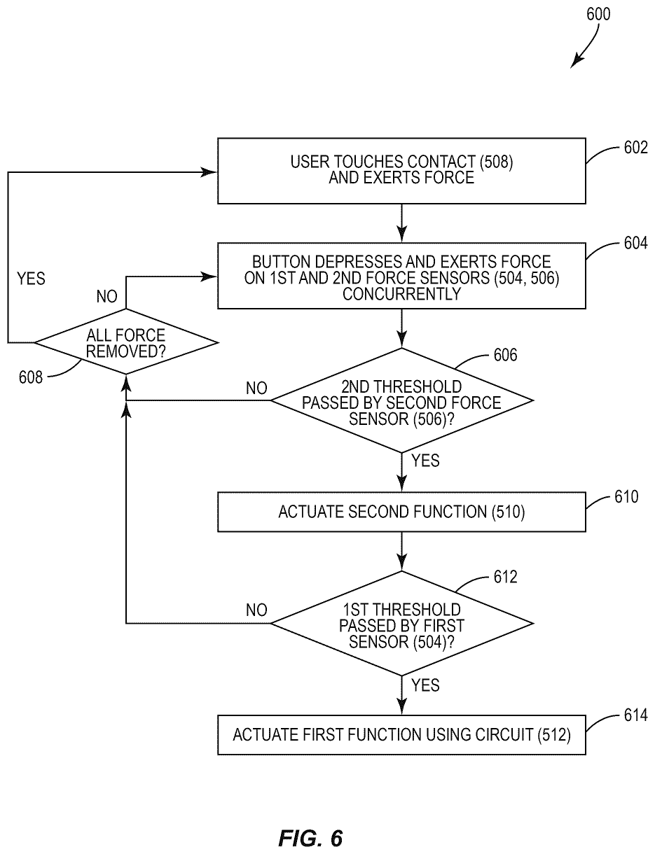

An exemplary process 600 for using a two-function trigger is set forth with reference to FIG. 6. The process 600 begins when the user touches the button (or contact 508) and exerts a force thereon (block 602). The button is depressed and exerts a force on the first and second force sensors 504, 506 concurrently (block 604). The process 600, and particularly the control circuit 502, determines if the second threshold is passed by the second force sensor 506 (block 606). If the answer is no, then there may be a determination if all force has been removed (block 608). If the answer to block 608 is yes, then the process 600 returns to block 602. If the answer to block 608 is no, then the process 600 returns to block 604.

If, however, the answer to block 606 is yes, then the control circuit 502 actuates the second function (block 610) using the second function circuit 510 and may optionally provide feedback using the feedback circuit 514. The control circuit 502 then determines if the first threshold is passed by the first force sensor 504 (block 612). If the answer to block 612 is no, then the process iterates through block 608, as previously discussed. If, however, the answer to block 612 is yes, then the control circuit 502 may actuate the first function (block 614) using the first function circuit 512.

Note further that while the above description is focused on a mobile terminal as a primary device and a fingerprint sensor as a secondary function, the present disclosure is not so limited. Other possible use cases include a camera, where the primary function is taking the photo and the secondary function is autofocus, auto flash, zoom, slow motion, or other functions. Still, another use case is an audio device, where the primary function is perhaps on/off, and the secondary function is volume or channel selection. It should be appreciated that in some use cases, there may be more than two functions associated with the trigger, where different force thresholds trigger different functions or one of the functions may be a continuum (e.g., volume or zoom). Still, another option would be to allow programming of the threshold for the second function to align with a user's own perception of the best contrast between the first threshold and the second threshold.

In addition to the use cases set forth above, the two-function trigger of the present disclosure may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

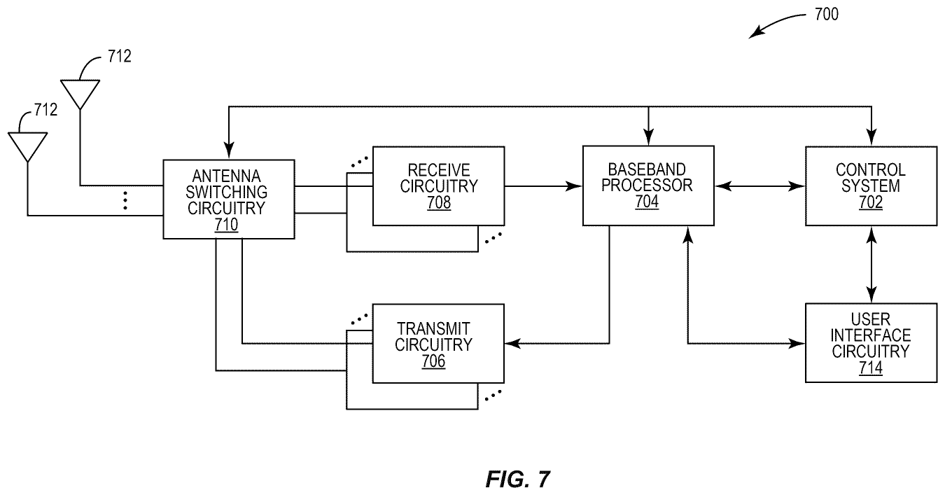

For the sake of completeness, an exemplary user element is described with reference to FIG. 7. More specifically, the concepts described above may be implemented in various types of user elements 700, such as mobile terminals, smart watches, tablets, computers, navigation devices, access points, and like wireless communication devices that support wireless communications, such as cellular, wireless local area network (WLAN), Bluetooth, and near field communications. The user elements 700 will generally include a control system 702, a baseband processor 704, transmit circuitry 706, receive circuitry 708, antenna switching circuitry 710, multiple antennas 712, and user interface circuitry 714, which may include the two-function trigger of the present disclosure. In a non-limiting example, the control system 702 can be a field-programmable gate array (FPGA) or an application-specific integrated circuit (ASIC), as an example. In this regard, the control system 702 can include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter of the receive circuitry 708 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 704 processes the digitized received signal to extract the information or data bits conveyed in the received signal. This processing typically comprises demodulation, decoding, and error correction operations. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710 to the antennas 712. The multiple antennas 712 and the replicated transmit and receive circuitries 706, 708 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A two-function trigger system comprising:
a contact configured to respond to a user's touch;
a first force sensor mechanically coupled to the contact and configured to actuate a first function when a first force threshold is reached or exceeded;
a control circuit;
a second force sensor coupled to the contact and configured to actuate a second function through the control circuit when a second force threshold is reached, the second force threshold less than the first force threshold; and
a feedback circuit coupled to the control circuit, the feedback circuit configured to provide feedback to a user responsive to the second force threshold being reached.

2. The two-function trigger system of claim 1, wherein the contact comprises a button.

3. The two-function trigger system of claim 1, wherein the first force sensor comprises a dome switch.

4. The two-function trigger system of claim 1, wherein the second force sensor comprises a capacitive-based force sensor.

5. The two-function trigger system of claim 1, wherein the feedback circuit is configured to provide a haptic feedback to the user.

6. The two-function trigger system of claim 1, wherein the feedback circuit is configured to provide an audible feedback to the user.

7. The two-function trigger system of claim 1, further comprising a fingerprint sensor associated with the contact.

8. The two-function trigger system of claim 7, wherein the second force sensor actuates the fingerprint sensor when the second force threshold is reached.

9. The two-function trigger system of claim 1, wherein the first force sensor is coupled to the control circuit.

10. A device comprising:
a user interface comprising a contact;
a two-function trigger system associated with the contact, the two-function trigger system comprising:
a first force sensor mechanically coupled to the contact and configured to actuate a first function when a first force threshold is reached or exceeded;
a control circuit;
a second force sensor coupled to the contact and configured to actuate a second function through the control circuit when a second force threshold is reached, the second force threshold less than the first force threshold; and
a feedback circuit coupled to the control circuit, the feedback circuit configured to provide feedback to a user responsive to the second force threshold being reached.

11. The device of claim 10, wherein the device comprises a mobile terminal.

12. The device of claim 11, wherein the contact comprises a button.

13. The device of claim 12, wherein the user interface further comprises a screen and the first function locks the screen.

14. The device of claim 11, further comprising a fingerprint sensor and the second function actuates the fingerprint sensor.

15. The device of claim 10, wherein the device comprises a camera.

16. The device of claim 15, wherein the first function takes a picture.

17. The device of claim 16, wherein the second function invokes an autofocus algorithm.

18. A method of actuating a two-function trigger, comprising:
pressing a contact with force less than a first force threshold but equal to or greater than a second force threshold;
responsive to the second force threshold being met, actuating a second function in a device, and providing feedback to a user;
responsive to the first force threshold being met, actuating a first function in the device.

19. The method of claim 18, wherein actuating the second function comprises actuating a fingerprint sensor.

20. The method of claim 18, wherein actuating the first function comprises locking a screen on a mobile terminal.
